(19) United States
(12) Patent Application Publication
(10) Pub. No.: US 2019/0011829 A1
(43) Pub. Date: Jan. 10, 2019

(54) PHOTOMASK AND METHOD FOR MANUFACTURING ACTIVE SWITCH ARRAY SUBSTRATE USING SAME

(71) Applicants: HKC Corporation Limited, Shenzhen City, Guangdong (CN); Chongqing HKC Optoelectronics Technology Co., Ltd., Chongqing (CN)

(72) Inventor: Yu-Jen CHEN, Chongqing (CN)

(21) Appl. No.: 15/735,316

(22) PCT Filed: May 31, 2017
(86) PCT No.: PCT/CN2017/086639

§ 371 Date: Dec. 11, 2017

(30) Foreign Application Priority Data
May 2, 2017 (CN) 201710301666.4

(51) Int. Cl. G03F 1/52; G02F 1/1362; H01L 27/12; H01L 21/027

(52) U.S. Cl. CPC G03F 1/52; G02F 1/136209; H01L 27/1262; G02F 1/1368; H01L 21/0274; G02F 2001/136222; H01L 27/1288

(57) ABSTRACT

This application relates to a photomask and a method for manufacturing an active switch array substrate using same. The photomask includes: a light penetration region, including a light penetration substrate; a translucent region, disposed on the light penetration substrate and formed of chromium or a chromium compound; a light shielding region, disposed on the light penetration substrate; and reflective material layers of a plurality of fine lines, disposed between the translucent region and the light shielding region and formed of chromium or a chromium compound, where the light penetration rate of the photomask is regulated according to doping and a distribution density of a low reflective material, so that the light penetration rate of the translucent region is lower than the light penetration rate of the light transmitting region and is higher than the light penetration rate of the light shielding region.

### BACKGROUND

### Technical Field

This application relates to a manufacturing method, and in particular, to a photomask and a method for manufacturing an active switch array substrate using same.

### Related Art

With the progress of science and technology, spread of liquid crystal displays having a plurality of advantages such as power saving, no radiation, small volume, low power consumption, flat square, high resolution, and stable picture quality, especially, various information products nowadays, such as a mobile phone, a laptop computer, a digital camera, a PDA, and a liquid crystal screen, greatly improves the demand quantity of liquid crystal displays (LCD). Therefore, how to satisfy a pixel design that increasingly requires a high resolution and a thin film transistor liquid crystal display (TFT-LCD) having excellent characteristics such as high picture quality, good space utilization efficiency, low consumption power, and no radiation has gradually become the mainstream of the market. An active switch array substrate is one of important components composing a liquid crystal display.

A liquid crystal display includes a color filter substrate, an active switch array substrate, and liquid crystals filled between the two substrates. In a liquid crystal display of a relatively large size, to maintain a gap between the two substrates, a plurality of spacers is distributed within a liquid crystal layer to maintain the gap height to keep the two substrates parallel. In addition, a liquid crystal injection method mainly is a liquid crystal vacuum injection method, which has a long injection time, and is gradually replaced by One Drop Fill (ODF) at present, and design of the structure of a spacer needs to be updated. In a known technology, spherical spacers are distributed between liquid crystal layers. In this structure, when a pressure is applied to the substrates, a substrate may be damaged due to rolling of the spacers, or uneven distribution is generated in a pixel region due to random distribution, or even the product yield is affected due to a diffusion problem of the spacers. In recent years, photo spacers (PS) are formed by using a lithography technology, and the position, size, and height of the spacers are accurately controlled, so that the construction of conventional spherical spacers is replaced.

Functions of a spacer structure in a liquid crystal display lie in controlling a gap between a first substrate and a second substrate of the display. A liquid crystal material is mainly filled between an upper glass sheet and a lower glass sheet. Evenness of the gap between the upper glass sheet and the lower glass sheet cannot be well maintained without support of a spacer structure. However, evenness of the gap between the first substrate and the second substrate has important impact on maintenance of a display effect of the liquid crystal display and telecommunications quality thereof.

Active switch array substrates are further grouped into opposite substrates having red, green, and blue photoresist layers (RGB on CF), active switch array substrates having red, green, and blue photoresist layers in in-plane switching liquid crystal panels (RGB on Array/In-Plane Switching, IPS mode), and active switch array substrates having red, green, and blue photoresist layers in vertical alignment liquid crystal panels (RGB on Array/Vertical Alignment, VA mode). In this way, as regards pixel design about how to improve the resolution, design of a pixel structure of an active switch array substrate plays a key role, and a conventional red-green-blue-white photoresist layer four-color liquid crystal display has a relatively high transmittance and therefore has become a technology currently developed by a plurality of panel plants regarding Color on Array or Color on TFT (COA or COT). However, a photo spacer process needs to be added after a red-green-blue-white color photoresist process. Therefore, a great amount of materials are used, management and control is difficult, a process procedure is complicated, and investment in device is relatively high. Because a white photoresist and photo spacers are both made of transparent materials and the white photoresist has a price higher than that of the photo spacer material by at least 30%, a plurality of manufacturers is devoted to developing the photo spacer and replacing the white photoresist material with the photo spacer. However, actually, because the brightness sensing degree of the photo spacer is not sufficiently high and a through-hole is formed to be relatively small, the size of the white photoresist through-hole needs to be increased by over 50 μm so as to enable the exposed through-hole to be greater than 20 μm. In this way, the aperture ratio is greatly sacrificed, and difficulty in design is caused or a procedure yield is affected.

### SUMMARY

To resolve the foregoing technical problem, an objective of this application is to provide a photomask and a method for manufacturing an active switch array substrate using same, so as to improve the pixel aperture ratio and reduce photomask costs.

The objective of this application is achieved and the technical problem of this application is resolved by using the following technical solutions. A photomask provided according to this application comprises: a light penetration region, comprising a light penetration substrate; a translucent region, disposed on the light penetration substrate and formed of chromium or a chromium compound; a light shielding region, disposed on the light penetration substrate; and reflective material layers of a plurality of fine lines, disposed between the translucent region and the light shielding region, wherein the light penetration rate of the photomask is regulated according to doping and a distribution density of a low reflective material, so that the light penetration rate of the translucent region is lower than the light penetration rate of the light transmitting region and is higher than the light penetration rate of the light shielding region.

An objective of this application, a method for manufacturing an active switch array substrate, comprises: providing a first substrate; forming a first insulation layer on the first substrate; forming a plurality of active switch units on the first insulation layer; sequentially forming on the first insulation layer a plurality of photoresist layers arranged in parallel, to finish a color filter layer; simultaneously forming a plurality of photo spacers and a plurality of through-holes on the color filter layer, comprising: forming a light shielding material layer on the color filter layer, to cover the color filter layer; disposing a photomask on the light shielding material layer, wherein the photomask comprises a light penetration region, a light shielding region, and a translucent region; and performing exposure manufacturing and imaging manufacturing, to pattern the light shielding material layer, to form the plurality of photo spacers and the plurality of through-holes, wherein reflective material layers of a plurality of fine lines are added to an edge adjoiner between the translucent region and the light shielding region, and when the photomask contacts exposure, the reflective material layers of the plurality of fine lines enable the edge adjoiner between the translucent region and the light shielding region to generate slit optical interference, so that a through-hole formed by one of the plurality of photoresist layers is greater than 20 μm; and forming a transparent electrode layer on the color filter layer, wherein the light penetration rate of the photomask is regulated by regulating doping and a distribution density of a low reflective material.

Still another objective of this application, a photomask, comprises: a light penetration region, comprising a light penetration substrate; a translucent region, disposed on the light penetration substrate and formed of chromium or a chromium compound; a light shielding region, disposed on the light penetration substrate; and reflective material layers of a plurality of fine lines, disposed between the translucent region and the light shielding region, wherein the width of a fine line and the width of a gap of fine lines of the reflective material layers of the plurality of fine lines are in a range of 1 μm to 5 μm, when the photomask contacts exposure, the reflective material layers of the plurality of fine lines enable the edge adjoiner between the translucent region and the light shielding region to generate slit optical interference, a translucent film through a part of which exposed light is able to pass is formed in the translucent region, a light shielding film is formed in the light shielding region, the light penetration rate of the photomask is regulated according to doping and a distribution density of a low reflective material, the low reflective material is a group consisting of chromium metals and compounds thereof, the light penetration rate of the translucent region of the photomask is regulated by regulating doping amounts and distribution densities of the chromium metals and the compounds thereof, the light penetration rate of the translucent region is in a range of 30% to 70%, the light shielding region contains 0% of chromium, and the light penetration region contains about 98% of chromium.

The technical problem of this application may be further resolved by using the following technical measures.

In an embodiment of this application, the width of a fine line and the width of a gap of fine lines of the reflective material layers of the plurality of fine lines are in a range of 1 μm to 5 μm.

In an embodiment of this application, when the photomask contacts exposure, the reflective material layers of the plurality of fine lines enable the edge adjoiner between the translucent region and the light shielding region to generate slit optical interference.

In an embodiment of this application, a translucent film through a part of which exposed light is able to pass is formed in the translucent region, a light shielding film is formed in the light shielding region, and the light penetration rate of the translucent region is in a range of 30% to 70%.

In an embodiment of this application, the materials of the reflective material layers of the plurality of fine lines and the low reflective material are selected from a group consisting of chromium metals and compounds thereof.

In an embodiment of this application, in the manufacturing method, the low reflective material is selected from a group consisting of chromium and compounds thereof.

In an embodiment of this application, in the manufacturing method, the photomask is a gray-scale photomask, and reflective material layers of a plurality of fine lines are added to generate slit optical interference.

In an embodiment of this application, in the manufacturing method, the width of a fine line and the width of a gap of a plurality of fine lines are in a range of 1 μm to 5 μm.

This application can improve the pixel aperture ratio and reduce photomask costs.

### BRIEF DESCRIPTION OF THE DRAWINGS

FIG. 1a is a schematic cross-section diagram of an exemplary active switch array substrate including a red-green-blue-white photoresist layer and a photo spacer;

FIG. 1b is a schematic cross-section diagram of an exemplary active switch array substrate including a red-green-blue-white photoresist layer, a photo spacer, and a photomask;

FIG. 2a is a schematic cross-section diagram of an active switch array substrate including a red-green-blue-white photoresist layer, a photo spacer, and a photomask according to a method of this application;

FIG. 2b is a schematic cross-section diagram of an active switch array substrate including a red-green-blue-white photoresist layer and a photo spacer according to a method of this application; and

FIG. 3 is a schematic diagram of reflective material layer fine lines and gaps according to a method of this application.

### DETAILED DESCRIPTION

The following embodiments are described with reference to the accompanying drawings, which are used to exemplify specific embodiments for implementation of this application. Terms about directions mentioned in this application, such as “on”, “below”, “front”, “back”, “left”, “right”, “in”, “out”, and “side surface” merely refer to directions of the accompanying drawings. Therefore, the used terms about directions are used to describe and understand this application, and are not intended to limit this application.

The accompanying drawings and the description are considered to be essentially exemplary, rather than limitative. In figures, units with similar structures are represented by using a same reference number. In addition, for understanding and ease of description, a size and a thickness of each component shown in the accompanying drawings are arbitrarily shown, but this application is not limited thereto.

In the accompanying drawings, for clarity, thicknesses of a layer, a film, a panel, an area, and the like are enlarged. In the accompanying drawings, for understanding and ease of description, thicknesses of some layers and areas are enlarged. It should be understood that when a component such as a layer, a film, an area, or a substrate is described to be “on” “another component”, the component may be directly on the another component, or there may be an intermediate component.

In addition, in this specification, unless otherwise explicitly described to have an opposite meaning, the word “include” is understood as including the component, but not excluding any other component. In addition, in this specification, “on” means that a component is located on or below a target component, but does not mean that the component needs to be located on top of a gravity direction.

To further describe the technical means adopted in this application to achieve a predetermined invention objective and effects of this application, specific implementations, structures, features, and effects of a photomask and a method for manufacturing an active switch array substrate using same provided according to this application are described in detail below with reference to the drawings and preferred embodiments.

A liquid crystal panel of this application may include an active switch (for example, a thin film transistor (TFT)) substrate, a color filter (CF) substrate, and a liquid crystal layer formed between the two substrates.

In an embodiment, the liquid crystal panel of this application may be a curved-surface display panel.

In an embodiment, an active switch (such as a TFT) and a CF of this application may be formed on the same substrate.

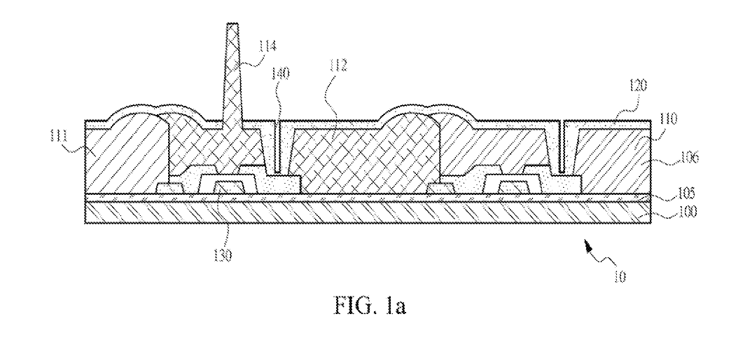

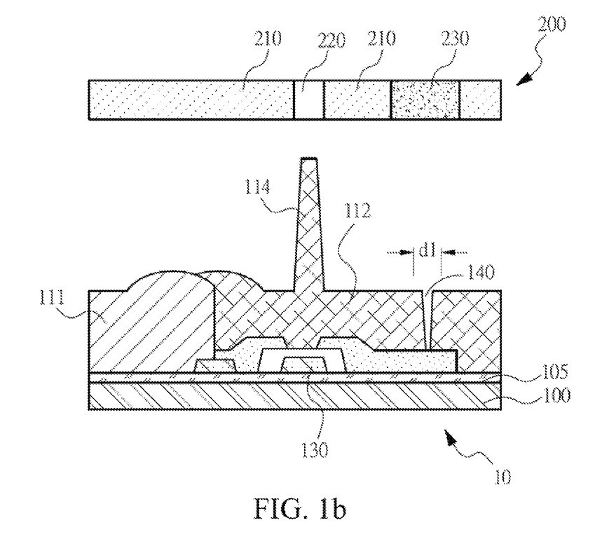

FIG. 1a is a schematic cross-section diagram of an exemplary active switch array substrate including a red-green-blue-white photoresist layer and a photo spacer. Referring to FIG. 1a, an active switch array substrate 10 includes: a first substrate 100; a first insulation layer 105, disposed on the first substrate 100; a plurality of active switch units 130, disposed on the first insulation layer 105; a color filter layer 106, disposed on the first insulation layer 105 and including a plurality of first photoresist layers 110, second photoresist layers 111, and third photoresist layers 112 that are arranged in parallel; a plurality of photo spacers 114, disposed on the color filter layer 106, where the material photo spacers 114 is the same as that of the plurality of third photoresist layers 112, and the plurality of third photoresist layers 112 includes at least one through-hole 140; and a transparent electrode layer 120, disposed on the color filter layer 106.

FIG. 1b is a schematic cross-section diagram of an exemplary active switch array substrate including a red-green-blue-white photoresist layer, a photo spacer, and a photomask. Referring to FIG. 1a and FIG. 1b, an active switch array substrate 10 includes: a first substrate 100; a first insulation layer 105, disposed on the first substrate 100; a plurality of active switch units 130, disposed on the first insulation layer 105; a color filter layer 106, disposed on the first insulation layer 105 and including a plurality of first photoresist layers 110, second photoresist layers 111, and third photoresist layers 112 that are arranged in parallel; a plurality of photo spacers 114, disposed on the color filter layer 106, where the material of the photo spacers 114 is the same as that of the plurality of third photoresist layers 112, the plurality of third photoresist layers 112 includes at least one through-hole 140, and the through-hole 140 has a size of d1; and a transparent electrode layer 120, disposed on the color filter layer 106.

In an embodiment, a photomask 200 includes a light shielding region 230 containing 0% of chromium, a light penetration region 220 containing about 98% of chromium, and a translucent region 210.

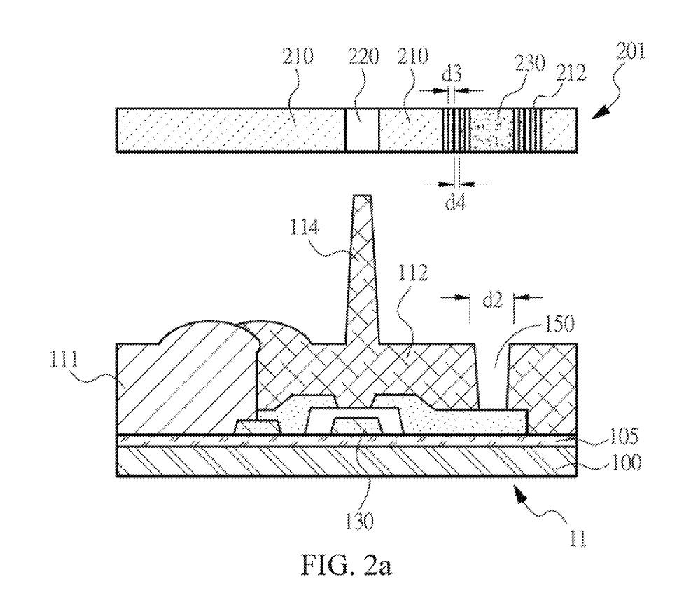

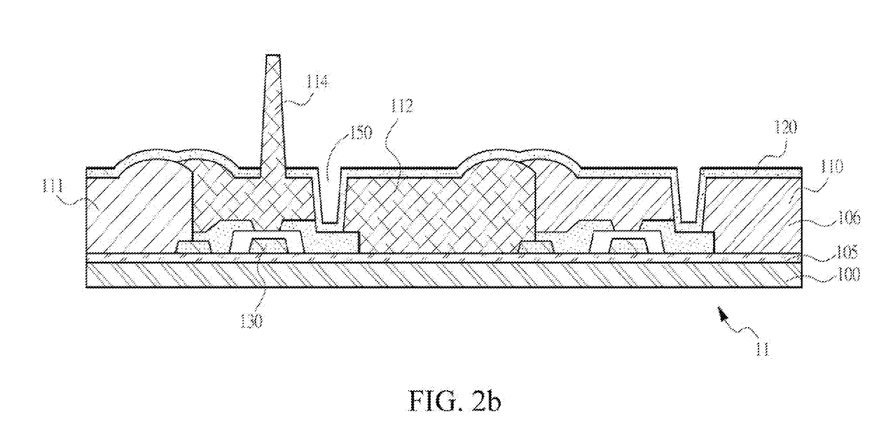

FIG. 2a is a schematic cross-section diagram of an active switch array substrate including a red-green-blue-white photoresist layer, a photo spacer, and a photomask according to a method of this application. FIG. 2b is a schematic cross-section diagram of an active switch array substrate including a red-green-blue-white photoresist layer and a photo spacer according to a method of this application. Referring to FIG. 2b, an active switch array substrate 11 includes: a first substrate 100; a first insulation layer 105, disposed on the first substrate 100; a plurality of active switch units 130, disposed on the first insulation layer 105; a color filter layer 106, disposed on the first insulation layer 105 and including a plurality of first photoresist layers 110, second photoresist layers 111, and third photoresist layers 112 that are arranged in parallel; a plurality of photo spacers 114, disposed on the color filter layer 106, where the material of the photo spacers 114 is the same as that of the plurality of third photoresist layers 112, and the plurality of third photoresist layers 112 includes at least one through-hole 150; and a transparent electrode layer 120, disposed on the color filter layer 106.

Referring to FIG. 2a and FIG. 2b, in an embodiment of this application, an active switch array substrate 11 includes: a first substrate 100; a first insulation layer 105, disposed on the first substrate 100; a plurality of active switch units 130, disposed on the first insulation layer 105; a color filter layer 106, disposed on the first insulation layer 105 and including a plurality of first photoresist layers 110, second photoresist layers 111, and third photoresist layers 112 that are arranged in parallel; a plurality of photo spacers 114, disposed on the color filter layer 106, where the material of the photo spacers 114 is the same as that of the plurality of third photoresist layers 112, the plurality of third photoresist layers 112 includes at least one through-hole 150, and the through-hole 150 has a size of d2; and a transparent electrode layer 120, disposed on the color filter layer 106.

In an embodiment, the size d2 of the through-hole 150 is greater than 20 μm.

In an embodiment, the photo spacer 114 is integrated with the third photoresist layer 112 using the same material.

In an embodiment, the shape of a combination of the photo spacer 114 and the third photoresist layer 112 is a raised shape with a narrow upper part and a wide lower part.

In an embodiment, a photomask 201 includes: a light shielding region 230 containing 0% of chromium, a light penetration region 220 containing about 98% of chromium, a translucent region 210, and reflective material layers of a plurality of fine lines 212, to generate slit optical interference, and the width d3 of a fine line and the width d4 of a gap are in a range of 1 μm to 5 μm.

Referring to FIG. 2a and FIG. 2b, in an embodiment of this application, an active switch array substrate 11 includes: a first substrate 100; a first insulation layer 105, disposed on the first substrate 100; a plurality of active switch units 130, disposed on the first insulation layer 105; a color filter layer 106, disposed on the first insulation layer 105 and including a plurality of photoresist layers 110, 111, and 112; a plurality of photo spacers 114, disposed on the color filter layer 106, where the material of the photo spacers 114 is the same as that of one (for example, a white photoresist layer) of the plurality of photoresist layers 110, 111, and 112, forming of one of the plurality of photoresist layers 110, 111, and 112 and the plurality of photo spacers 114 is exposed by using a photomask 201, the photomask 201 includes a light penetration region 220, a translucent region 210, and a light shielding region 230, reflective material layers of a plurality of fine lines 212 are added to an edge adjoiner between the translucent region 210 and the light shielding region 230, and when the photomask 201 contacts exposure, the reflective material layers of the plurality of fine lines 212 enable the edge adjoiner between the translucent region 210 and the light shielding region 230 to generate slit optical interference, so that a through-hole 150 of one of the plurality of photoresist layers 110, 111, and 112 has a size d2 greater than 20 μm; and a transparent electrode layer 120, disposed on the color filter layer 106.

Referring to FIG. 2a and FIG. 2b, in an embodiment of this application, a method for manufacturing an active switch array substrate 11 includes: providing a first substrate 100; forming a first insulation layer 105 on the first substrate 100; forming a plurality of active switch units 130 on the first insulation layer 105; sequentially forming on the first insulation layer 105 a plurality of photoresist layers 110, 111, and 112 arranged in parallel, to finish a color filter layer 106; simultaneously forming a plurality of photo spacers 114 and a plurality of through-holes 105 on the color filter layer 106, including: forming a light shielding material layer on the color filter layer 106, to cover the color filter layer 106; disposing a photomask 201 on the light shielding material layer, where the photomask 201 includes a light penetration region 220, a light shielding region 230, and a translucent region 210; and performing exposure manufacturing and imaging manufacturing, to pattern the light shielding material layer, to form the plurality of photo spacers 114 and the plurality of through-holes 105, where reflective material layers of a plurality of fine lines 212 are added to an edge adjoiner between the translucent region 210 and the light shielding region 230, and when the photomask 201 contacts exposure, the reflective material layers of the plurality of fine lines 212 enable the edge adjoiner between the translucent region 210 and the light shielding region 230 to generate slit optical interference, so that a through-hole 105 formed by one 112 of the plurality of photoresist layers 110, 111, and 112 is greater than 20 μm; and forming a transparent electrode layer 120 on the color filter layer 106, where the light penetration rate of the photomask 201 is regulated by regulating doping and a distribution density of a low reflective material.

In an embodiment, the light penetration rate of the translucent region 210 is in a range of 30% to 70%.

In an embodiment, the low reflective material is a group consisting of chromium and compounds thereof.

In an embodiment, design of the translucent region 210 enables the through-hole 150 formed by one photoresist layer 112 among the plurality of photoresist layers 110, 111, and 112 to be greater than 20 μm.

In an embodiment, the photomask 201 is a gray-scale photomask, and reflective material layers of a plurality of fine lines 212 are added to generate slit optical interference, and the width d3 of a fine line and the width d4 of a gap are in a range of 1 μm to 5 μm.

In an embodiment, the plurality of photo spacers 114 forms at least one offset by using the same photomask 201.

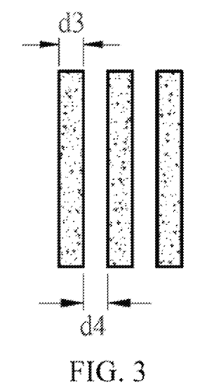

FIG. 3 is a schematic diagram of reflective material layer fine lines and gaps according to a method of this application. Referring to FIG. 3, FIG. 2a, and FIG. 2b, a photomask 201 includes: a light penetration region 220, including a light penetration substrate; a translucent region 210, disposed on the light penetration substrate and formed of chromium or a chromium compound; a light shielding region 230, disposed on the light penetration substrate; and reflective material layers of a plurality of fine lines 212, disposed between the translucent region 210 and the light shielding region 230, where the reflective material layers of the plurality of fine lines 212 may be formed by, for example, chromium or a chromium compound, but is not limited thereto, and may also be formed by another metal or compound with a light absorption property. The light penetration rate of the photomask 201 is regulated according to doping and a distribution density of a low reflective material, so that the light penetration rate of the translucent region 210 is lower than the light penetration rate of the light penetration region 220 and is higher than the light penetration rate of the light shielding region 230.

In an embodiment, when the photomask 201 contacts exposure, the reflective material layers of the plurality of fine lines 212 enable the edge adjoiner between the translucent region 210 and the light shielding region 230 to generate slit optical interference.

In an embodiment, the fine line width d3 of a fine line and the distance d4 of between fine lines of the reflective material layers of the plurality of fine lines 212 are in a range of 1 μm to 5 μm.

In an embodiment, a translucent film through a part of which exposed light is able to pass is formed in the translucent region 210, and a light shielding film is formed in the light shielding region 230.

In an embodiment, materials of the reflective material layers of the plurality of fine lines 212 and the low reflective material are selected from a group consisting of chromium metals and compounds thereof.

In an embodiment, the light penetration rate of the translucent region 210 is in a range of 30% to 70%.

In an embodiment, the photomask 201 is a gray-scale photomask, and reflective material layers of a plurality of fine lines 212 are added to generate slit optical interference, and the width d3 of a fine line and the width d4 of a gap are in a range of 1 μm to 5 μm.

In different embodiments, a multi-gray-scale photomask may be divided into a gray-tone mask and a half tone mask. The gray-tone mask achieves an effect of half-exposure by manufacturing a hair crack with a resolution lower than that of an exposure machine and covering a part of a light source by means of the hair crack part. On the other hand, the half tone mask performs half-exposure by using a “half-penetration” film. Because in the foregoing two methods, three exposure levels, “an exposed part”, “a half-exposed part” and “an unexposed part”, present after once exposure process, photoresists of two thicknesses are formed after development (by means of such a photoresist thickness difference, figures may be transcribed to a panel substrate using a relatively small quantity, to improve a panel production efficiency). A photomask cost of a half tone mask is slightly higher than that of a common photomask.

This application can improve the pixel aperture ratio and reduce photomask costs.

Terms such as “in some embodiments” and “in various embodiments” are repeatedly used. Usually, the terms do not refer to a same embodiment; but they may also refer to a same embodiment. Words such as “comprise”, “have”, “include” are synonyms, unless other meanings are indicated in the context.

The foregoing descriptions are merely preferred embodiments of this application, and are not intended to limit this application in any form. Although this application has been disclosed above through the preferred embodiments, the embodiments are not intended to limit this application. Any person skilled in the art can make some equivalent variations or modifications according to the foregoing disclosed technical content without departing from the scope of the technical solutions of this application to obtain equivalent embodiments. Any simple amendment, equivalent change or modification made to the foregoing embodiments according to the technical essence of this application without departing from the content of the technical solutions of this application shall fall within the scope of the technical solutions of this application.

What is claimed is:

1. A photomask, comprising:
a light penetration region, comprising a light penetration substrate;
a translucent region, disposed on the light penetration substrate and formed of chromium or a chromium compound;
a light shielding region, disposed on the light penetration substrate; and
a reflective material layers of a plurality of fine lines, disposed between the translucent region and the light shielding region,
wherein the light penetration rate of the photomask is regulated according to doping and a distribution density of a low reflective material, so that the light penetration rate of the translucent region is lower than the light penetration rate of the light penetration region and is higher than the light penetration rate of the light shielding region.

2. The photomask according to claim 1, wherein the width of a fine line of the reflective material layers of the plurality of fine lines is in a range of 1 μm to 5 μm.

3. The photomask according to claim 1, wherein the width of a gap between fine lines of the reflective material layers of the plurality of fine lines is in a range of 1 μm to 5 μm.

4. The photomask according to claim 1, wherein when the photomask contacts exposure, the reflective material layers of the plurality of fine lines enable an edge adjoiner between the translucent region and the light shielding region to generate slit optical interference.

5. The photomask according to claim 1, wherein a translucent film through a part of which exposed light is able to pass is formed in the translucent region, and a light shielding film is formed in the light shielding region.

6. The photomask according to claim 5, wherein the light penetration rate of the translucent region is in a range of 30% to 70%.

7. The photomask according to claim 1, wherein the materials of the reflective material layers of the plurality of fine lines and the low reflective material are selected from a group consisting of chromium metals and compounds thereof.

8. A method for manufacturing an active switch array substrate, comprising:
providing a first substrate;
forming a first insulation layer on the first substrate;
forming a plurality of active switch units on the first insulation layer;
sequentially forming on the first insulation layer a plurality of photoresist layers arranged in parallel, to finish a color filter layer;
simultaneously forming a plurality of photo spacers and a plurality of through-holes on the color filter layer, comprising:
forming a light shielding material layer on the color filter layer, to cover the color filter layer;
disposing a photomask on the light shielding material layer, wherein the photomask comprises a light penetration region, a light shielding region, and a translucent region; and
performing exposure manufacturing and imaging manufacturing, to pattern the light shielding material layer, to form the plurality of photo spacers and the plurality of through-holes, wherein reflective material layers of a plurality of fine lines are added to an edge adjoiner between the translucent region and the light shielding region, and when the photomask contacts exposure, the reflective material layers of the plurality of fine lines enable the edge adjoiner between the translucent region and the light shielding region to generate slit optical interference, so that a through-hole formed by one of the plurality of photoresist layers is greater than 20 μm; and
forming a transparent electrode layer on the color filter layer, wherein
the light penetration rate of the photomask is regulated by regulating doping and a distribution density of a low reflective material.

9. The method for manufacturing an active switch array substrate according to claim 8, wherein the low reflective material is a group consisting of chromium and compounds thereof.

10. The method for manufacturing an active switch array substrate according to claim 8, wherein the photomask is a gray-scale photomask, and reflective material layers of a plurality of fine lines are added to generate slit optical interference.

11. The method for manufacturing an active switch array substrate according to claim 8, wherein the width of a fine line of the reflective material layers of the plurality of fine lines is in a range of 1 μm to 5 μm.

12. The method for manufacturing an active switch array substrate according to claim 8, wherein the width of a gap between fine lines of the reflective material layers of the plurality of fine lines is in a range of 1 μm to 5 μm.

13. A photomask, comprising:
a light penetration region, comprising a light penetration substrate;
a translucent region, disposed on the light penetration substrate and formed of chromium or a chromium compound;
a light shielding region, disposed on the light penetration substrate; and
reflective material layers of a plurality of fine lines, disposed between the translucent region and the light shielding region, wherein
the width of a fine line and the width of a gap of fine lines of the reflective material layers of the plurality of fine lines are in a range of 1 μm to 5 μm;
when the photomask contacts exposure, the reflective material layers of the plurality of fine lines enable the edge adjoiner between the translucent region and the light shielding region to generate slit optical interference;
a translucent film through a part of which exposed light is able to pass is formed in the translucent region, and a light shielding film is formed in the light shielding region;
the light penetration rate of the photomask is regulated according to doping and a distribution density of a low reflective material; and
the low reflective material is a group consisting of chromium metals and compounds thereof, the light penetration rate of the translucent region of the photomask is regulated by regulating doping amounts and distribution densities of the chromium metals and the compounds thereof, the light penetration rate of the translucent region is in a range of 30% to 70%, and the light shielding region contains 0% of chromium and the light penetration region contains about 98% of chromium.
